(19) United States
(12) Patent Application Publication
(10) Pub. No.: US 2008/0102780 A1
(43) Pub. Date: May 1, 2008

(54) Mobile Device Equipped With Am Radio

(75) Inventor: Akira Okamoto, Niigata (JP)

Correspondence Address: PATENTTM.US, P. O. BOX 82788, PORTLAND, OR, 97282-0788, US

(73) Assignee: NIIGATA SEIMITSU CO., LTD., Niigata (JP)

(21) Appl. No.: 11/718,693

(22) PCT Filed: Nov. 10, 2005
(86) PCT No.: PCT/JP05/20583

§ 371 Date: May 4, 2007

(30) Foreign Application Priority Data
Nov. 11, 2004 (JP) 2004-327756

(51) Int. Cl. H04B 1/16; H05K 11/00

(52) U.S. Cl. 455/344; 455/556.1

(57) ABSTRACT

A mobile device equipped with an AM radio, wherein noise to be mixed with AM radio output audio can be reduced. A cellular phone 100 is a mobile device equipped with an AM radio, the mobile device comprising a telephone processing section 10 for performing a predetermined process, while displaying the operational contents on displays 32, 34; and an AM radio tuner section 20, integral to the telephone processing section 10, for receiving an AM radio broadcast and outputting a demodulated audio signal. The mobile device includes an operating section 30 for instructing the AM radio tuner section 20 to commence the reception of the AM radio broadcast: and a control section 40 for changing the display state of the displays 32, 34 when the operating section 30 is used to instruct a reception commencement.

### TECHNICAL FIELD

The present invention relates to a mobile device such as a cellular phone with an AM radio function.

### BACKGROUND ART

Recently, a cellular phone having various functions in addition to the original telephone functions is commonly used. For example, a cellular phone provided with an AM radio broadcast tuner function, an FM radio broadcast tuner function, a television tuner function and the like has been known (for example, see Patent Document 1). With the cellular phone, a user can select the AM radio broadcast tuner function and the like which the user wants to play by operating the operating part while viewing the display part.

### [Patent Document 1]

Japanese Patent Laid-Open No. 2002-101164 (pages 3 to 5, FIGS. 1 to 6)

In case where the cellular phone equipped with a display part disclosed by the Patent Document 1 has the AM radio broadcast tuner function, there is a problem in that noise caused by the display part is mixed with the output audio of the AM radio. Particularly, the recent cellular phone has improved functions such as a camera and mail sender and receiver and the like. In order to display contents of these improved functions finely and clearly, a high-resolution TFT-type color liquid crystal display is often used. In addition, the recent cellular phone has been significantly downsized. If the AM radio broadcast tuner function is included in a single package, it is inevitable that a bar antenna serving as an AM radio antenna and the crystal liquid display device are arranged closely to each other, thus, noise generated when the liquid crystal display device is driven cannot be avoided to be mixed with the output audio of the AM radio broadcast.

The present invention has been made in view of the abovementioned circumstances and intends to provide a mobile device equipped with an AM radio that can reduce noise to be mixed with the output audio of the AM radio.

### DISCLOSURE OF THE INVENTION

In order to solve the abovementioned problem, the mobile device equipped with an AM radio of the invention has a processing unit integrated with an AM radio tuner unit, wherein the processing unit performs a predetermined process while displaying operational contents on the display unit and the AM radio tuner unit receives the AM radio broadcast and outputs a demodulated audio signal, comprising: an operating unit for providing an instruction to commence the reception of the AM radio broadcast by the AM radio tuner unit and a display state controlling unit for changing the display state of the display unit when the instruction to commence the reception by using the operating unit is provided. Particularly, the display unit in a displaying operation is a noise source to the AM radio tuner unit, and the display state controlling unit changes the display state of the display unit so as to reduce noise to be mixed into the AM radio tuner unit from the display unit. The display state of the display unit is changed when the AM radio broadcast is received in such a manner, noise to be mixed with an output audio whose noise source is the display unit can be reduced.

It is also desirable that the abovementioned display unit is a color liquid crystal display device. The recent mobile devices are often provided with a color liquid crystal display device driven by an active matrix in a TFT type in consideration of improvement in the clearness of display, fast response and the like. It is well known that the color liquid crystal display device is a big noise source to the AM radio tuner in comparison with the liquid crystal display device driven by a segment electrode that performs monochrome display. The noise included in the output audio when the AM radio is used can be reduced by changing a display state in case where the color liquid crystal display is used.

It is desirable that the process performed by the abovementioned processing unit is a speech processing as a portable telephone. Although various functions are added as more and more functions are to be provided for the recent cellular phone, it can reduce the noise even if an AM radio receiving function is added as one of the additional functions. Particularly, as the recent display of the cellular phone is to have a bigger screen, noise is inevitably generated due to the operation of the display unit. The noise, however, can be reduced if the display state of the display unit is changed when the AM radio is used.

It is also desirable that the abovementioned display unit has a plurality of divided regions where display operation can be selectively stopped, and the display state controlling unit stops display operation of a part of the plurality of divided regions when an instruction to commence the reception is provided. That can reduce an area of the display that will be a noise source so that the amount of noise included in the output audio of the AM radio can be reduced.

It is desirable that information on the broadcast contents being received by the abovementioned AM radio tuner unit is displayed instead of the operational contents of the processing unit or together with the operational contents in the broadcast contents display control unit for displaying them on the display unit and remaining divided regions in which a displaying operation is not stopped. That can reduce noise included in the output audio and improve operability when the AM radio is used.

It is desirable that the abovementioned AM radio tuner unit has a bar antenna whose magnetic core is wound with a coil, and that remaining divided regions in which display operation is not stopped are arranged in one of the spaces separated in the middle of longitudinal sides in a package having a solid shape oblong in one direction, and the bar antenna is arranged apart in the other space. Alternatively, it is desirable that the abovementioned AM radio tuner unit has a bar antenna whose magnetic core is wound with a coil, and that more than half of the remaining divided regions in which display operation is not stopped are arranged in one of the spaces separated in the middle of longitudinal sides in a package having a solid shape oblong in one direction, and the bar antenna is arranged apart in the other space. Alternatively, it is desirable that the abovementioned AM radio tuner unit has a bar antenna whose magnetic core is wound with a coil, and that the bar antenna is arranged along the edge of the package that is furthermost from the remaining divided regions in which display operation is not stopped in a package having a solid shape oblong in one direction. That can reduce noise to be mixed with via the bar antenna when the AM radio broadcast is received.

It is also desirable that the abovementioned display unit has a plurality of display regions which are set in different places, and that the display state controlling unit stops display operation of a part of the plurality of display regions when an instruction to commence the reception is provided. That can reduce the area of the display which will be a noise source so that it can reduce the amount of noise included in the output audio of the AM radio.

It is desirable that the abovementioned display state controlling unit stops the display operation for the display region with the biggest area. This make it possible to eliminate the biggest noise source, thereby effectively reduce the noise.

It is also desirable that the abovementioned display state controlling unit stops the operation of the other display regions except for the display region with the smallest area. This makes it possible to minimize the noise when there are many display regions.

It is desirable that the abovementioned AM radio tuner unit has a bar antenna whose magnetic core is wound with a coil, and that remaining display regions in which display operation is not stopped are arranged in one of the spaces separated in the middle of longitudinal sides in a package having a solid shape oblong in one direction, and the bar antenna is arranged apart in the other space. Alternatively, it is desirable that the abovementioned AM radio tuner unit has a bar antenna whose magnetic core is wound with a coil, and that more than half of the remaining display regions in which display operation is not stopped are arranged in one of the spaces separated in the middle of longitudinal sides in a package having a solid shape oblong in one direction, and the bar antenna is arranged apart in the other space. Alternatively, it is desirable that the abovementioned AM radio tuner unit has a bar antenna whose magnetic core is wound with a coil, and that the bar antenna is arranged along the edge of the package that is furthermost from the remaining display regions in which display operation is not stopped in a package having a solid shape oblong in one direction. That can reduce noise to be mixed with via the bar antenna when the AM radio broadcast is received.

It is also desirable that the abovementioned display state controlling unit stops display operation of the display unit when an instruction to commence the reception is provided. This makes it possible to avoid influence of the display unit as a noise source thereby occurrence of noise caused by the display unit can be eliminated.

It is also desirable that channel selection instruction for switching the receiving frequency of the broadcasting wave to be received by the AM radio tuner unit is provided by means of the operating unit, and that the display state controlling unit temporally releases a stopped state of display operation of the display unit when the channel selection instruction is provided. Both effects of improvement of operability and noise reduction can be achieved only by performing the requisite minimum display at the time of the channel selection.

It is also desirable that releasing of the stop state of display operation of the abovementioned display unit is performed on a part of the all display regions of the display unit. This makes it possible to reduce the noise temporally included in the output audio at the time of the channel selection.

It is also desirable to further include an audio output unit for outputting an audio corresponding to an audio signal output from the abovementioned AM radio tuner unit via a speaker, an earphone and the like, and the audio output unit performs a mute processing for breaking output of the audio when the stopping state of the display is released as the channel selection instruction is issued. It is thereby possible to prevent a rough audio with which noise is mixed at the time of the channel selection.

### BRIEF DESCRIPTION OF THE DRAWINGS

FIG. 1 is a diagram showing a configuration of a cellular phone of an embodiment;

FIG. 2 is a perspective diagram showing the cellular phone in-use;

FIG. 3 is a diagram showing a back side of a package of the cellular phone;

FIG. 4 is a flowchart showing an operational procedure of the cellular phone in receiving the AM radio broadcast;

FIG. 5 is a diagram showing two divided regions included in a main screen of the display;

FIG. 6 is a diagram showing a specific example where the contents of the AM radio broadcast is displayed on one divided region;

FIG. 7 is a diagram showing preferable arrangement of bar antenna corresponding to the case 1 and relationship between the bar antenna and the main screen;

FIG. 8 is a diagram showing preferable arrangement of bar antenna corresponding to the case 1 and relationship between the bar antenna and the main screen;

FIG. 9 is a diagram showing preferable arrangement of bar antenna corresponding to the case 2 and relationship between the bar antenna and the auxiliary screen;

FIG. 10 is a diagram showing preferable arrangement of bar antenna corresponding to the case 2 and relationship between the bar antenna and the auxiliary screen; and

FIG. 11 is a flowchart showing an operational procedure of an exemplary modification of the cellular phone in receiving the AM radio broadcast.

### BEST MODE FOR CARRYING OUT THE INVENTION

A cellular phone equipped with an AM radio of an embodiment to which the present invention is applied will be described in detail below with reference to the drawings. FIG. 1 is a diagram showing a configuration of a cellular phone of the embodiment. As shown in FIG. 1, a cellular phone 100 of the embodiment includes a telephone processing section 10, an antenna 12, a speaker 14, a microphone 16, an AM radio tuner section 20, a bar antenna 22, an audio output section 24, a speaker 26, an operating section 30, displays 32, 34, and a control section 40. In the embodiment, the telephone processing section 10, the AM radio tuner section 20, the audio output section 24, and the control section 40 are formed on a semiconductor substrate as a one-chip component with using a CMOS process.

The telephone processing section 10 performs processings required for making a call with another cellular phone, a fixed-line phone or the like by using the cellular phone 100 as a portable telephone. It performs the processing by sending or receiving a radio wave at a predetermined frequency with a base station (not shown) near itself via the antenna 12. Although it is omitted in FIG. 1, the cellular phone 100 has a function of sending or receiving mail and a function of accessing the Internet. It needs to exchange various types of data with external servers to achieve the functions. The telephone processing section 10 also performs the data-exchanging.

The AM radio tuner section 20 receives an AM radio broadcast by using the bar antenna 22 whose magnetic core is wound with a coil and demodulates the broadcast, and outputs an audio signal corresponding to the broadcast contents. The audio output section 24 is an audio outputting unit for amplifying an audio signal output from the AM radio tuner section 20 and outputs it from the speaker 26. An earphone may be used instead of or together with the speaker 26. When a mute signal is inputted, the audio output section 24 performs a mute processing for muting the output audio.

The operating section 30 is an operating unit having various keys needed in receiving the AM radio broadcast in addition to the numeral keys required for inputting a phone number, the “*” key and the “#” key. For example, the operating section 30 has a channel selection key for causing the frequency to shift up or down, which is required for channel selection in receiving an AM radio broadcast, and a volume key for increasing or decreasing the output volume. Dedicated keys may be allocated to these keys, or a part of a numeric keypad and the like may serve that purpose.

The display 32 on one side has a big screen for displaying various types of information required for operations of the cellular phone 100. For example, it displays a telephone number of the other party in making a phone call, a calling image and the caller's phone number in receiving a phone call, an image indicating the remaining amount of an internal battery, an antenna mark indicating the strength of the electric wave transmitted from the base station, a receiving frequency and a volume of output audio in receiving an AM radio broadcast or the like. In the embodiment, the cellular phone 100 with a folding package is used.

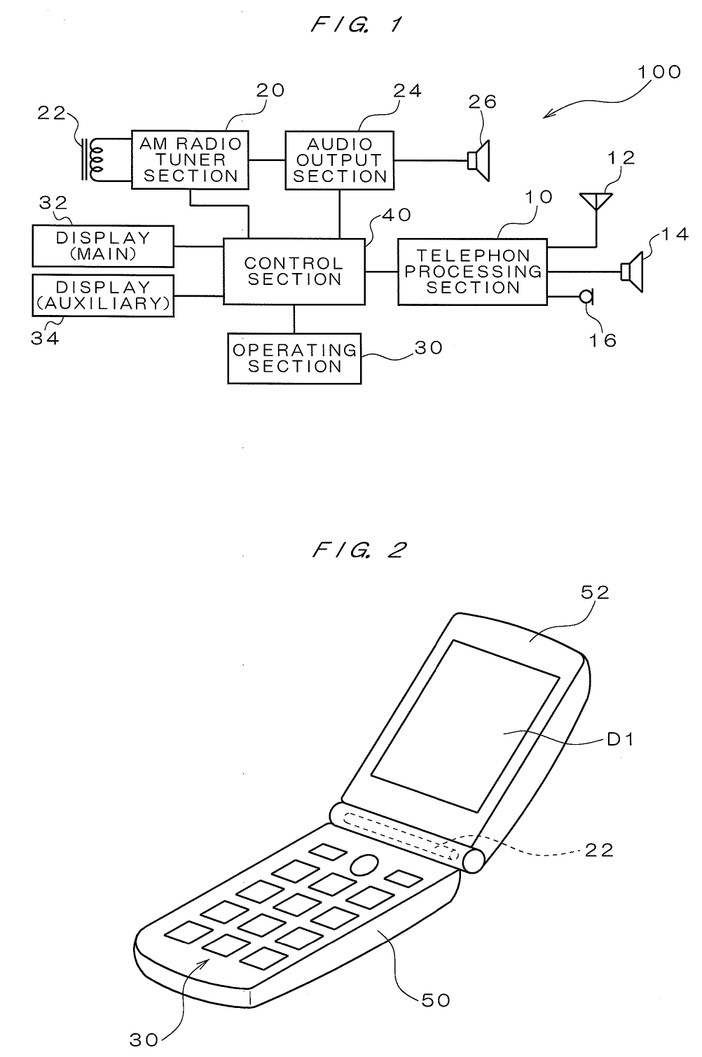

FIG. 2 is a perspective diagram showing the cellular phone 100 in-use. The cellular phone 100 has a package 50 having an operating section 30 which is mounted on one surface thereof and a package 52 having a display 32 which is mounted on one surface thereof. One end of longitudinal side of the package 50 and one end of longitudinal side of the package 52 are connected in foldable state so as to be able to open and close. As shown in FIG. 2, the numeral keys on the operating section 30 provided on the package 50 can be operated while the screen on the display 32 provided on the package 52 is being viewed, when the two packages 50 and 52 are opened. The screen of the display 32 can be checked for the display contents when a phone call is made, and it is referred as a “main screen” (D1) in following explanations.

The other display 34 is arranged where it can be seen when the two packages 50 and 52 are in folded state. The display 34 has a screen smaller than the main screen and displays various types of information required for operations of the cellular phone 100 in a supplementary manner. For example, a calling image when a phone call is received, a receiving frequency and a volume of output audio in receiving an AM radio broadcast are displayed. The screen of the display 34 is referred as an “auxiliary screen” (D2) hereinafter. FIG. 3 is a diagram showing a back side of the package 52, on which an auxiliary screen D2 of the display 34 is provided substantially in the center.

For both of the abovementioned two displays 32, 34, color liquid crystal display devices using TFT (Thin Film Transistor) for active devices driven by an active matrix are used. The color liquid crystal display device has a feature of a fast response and vivid color reproduction, which are noise sources for the AM radio tuner section 20. As such, in the embodiment, when the AM radio broadcast is received by using the AM radio tuner section 20, control is carried out for changing the display state of the displays 32, 34.

The control section 40 controls whole of the operations of the cellular phone 100. For example, when an AM radio broadcast is received, control for changing the receiving frequency of the AM radio tuner section 20 is performed in response to the operation of the channel selection key of the operating section 30, or for controlling to make a gain in the audio output section 24 to be variable is performed in response to the operation of the volume key. Also, controlling operations of displaying the receiving frequency or the output volume of the receiving AM radio broadcast is performed. Further, the control section 40 operates as display state control unit for changing a display state of the displays 32, 34 when it commences the reception of the AM radio broadcast.

The cellular phone 100 of the embodiment has such a configuration, whose operations will be described below. FIG. 4 is a flowchart showing an operational procedure of the cellular phone 100 when the AM radio broadcast is received, showing a controlling procedure relating to reception of an AM radio broadcast and display state control of the display 32 and the like. When the cellar phone 100 is turned on and operating, the control section 40 determines whether the AM radio is activated or not (step 100). In this step, it determines whether a user operates the operating section 30 to provide instruction to activate the AM radio or not (instruction to commence the reception). The user may provide instruction to activate the AM radio by operating the operating section 30 while viewing the hierarchical menu screen, in addition to pressing the key dedicated to activate the AM radio provided on the operating section 30. If the user does not provide instruction to activate, a negative determination is made in the step 100 and the judgment is repeated.

When the activation of the AM radio is instructed, an affirmative determination is made in the step 100. Then, the control section 40 changes the display state of the displays 32, 34 (step 101) and displays the contents of the AM radio broadcast to be received (step 102), and also performs the operation of receiving the AM radio broadcast by sending an instruction for the AM radio tuner section 20 (step 103). Details of the operation of changing the display state at the step 101 will be described later.

In parallel to the operation of receiving the AM radio broadcast, the control section 40 determines whether it is instructed to stop the AM radio or not (step 104). A user can provide the stop instruction by operating on the operating section 30. If the user does not provide a stop instruction, a negative determination is made in the step 104, then the procedure returns to the step 102 and procedures after the displaying the contents of the broadcast are repeated.

When a stop instruction for the AM radio is provided, an affirmative determination is made in the step 104. Then, the control section 40 sends the instruction for the AM radio tuner section 20 to terminate the operation of receiving the AM radio broadcast (step 105). Next, the control section 40 returns the display state of the displays 32, 34 to the original state (step 106), and returns to the step 100 and repeats the judgment whether the AM radio is activated or not.

Next, operations of changing the display state of the displays 32, 34 that are performed when the AM radio is activated will be described in detail. The display state is changed in order to reduce noises caused by the displays 32, 34 when the AM radio is received. There may be certain cases depending on which of the display 32 or the display 34 should be changed in its display state or how it is changed. The main two cases will be described below.

(Case 1) This is a case for dividing the main screen into multiple regions, displaying the contents of the AM radio broadcast by using only one of divided regions and stopping the operation of displaying in the other regions. FIG. 5 is a diagram showing two divided regions D11 and D12 included in the main screen D1 of the display 32. For example, the main screen D1 in a rectangular shape is divided into two by the divided regions D11 and D12 in lengthwise. As shown in FIG. 5, the display 32 is provided with two drivers 321 and 322 for scanning along the long side for displaying various types of information on the main screen D1 and a driver 323 for data along the short side. The driver 321 which is one of the drivers for scanning corresponds to one of the divided regions D11, while the other driver 322 corresponds to the other of the divided regions D12. When the AM radio broadcast is received, the drivers 321 and 323 are used and display is performed on only one of the divided regions D11. At this moment, the driver 322 is in a pausing state, in which no voltage is applied to the other divided region D12. The backlight is also divided in correspondence with each of the divided regions D11 and D12. It is controlled to turn out the backlight in correspondence with the divided region D12 in the pausing state.

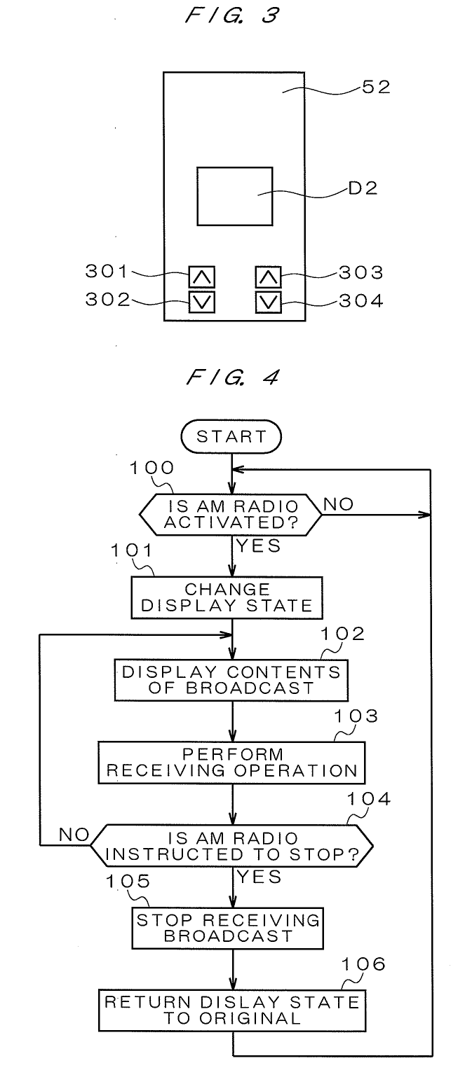

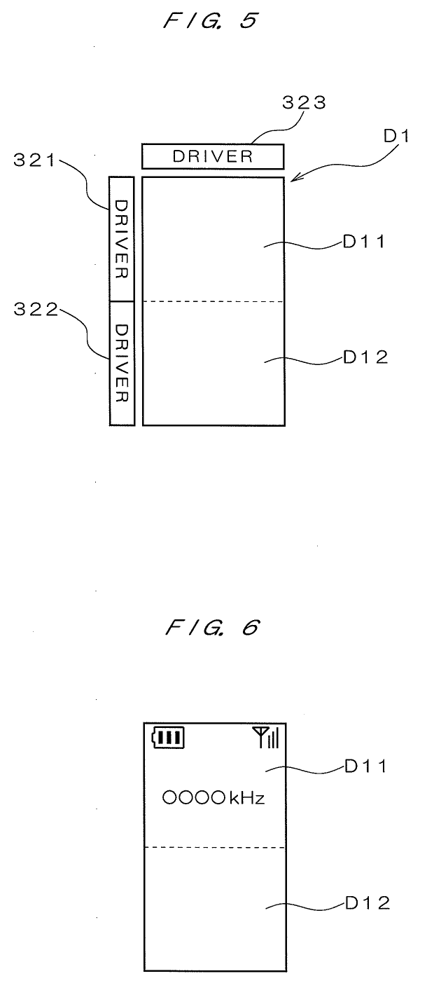

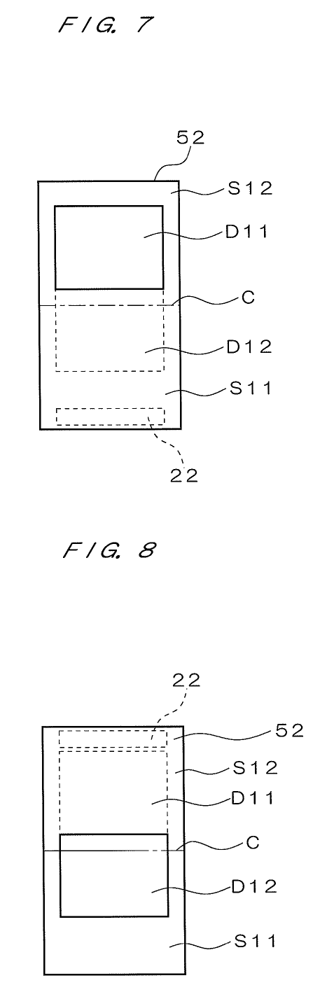

FIG. 6 is a diagram showing a specific example where the contents of the AM radio broadcast is displayed on one of the divided regions D11. On one of the divided regions D11, a receiving frequency (XXXX KHz) is displayed as the contents of the AM radio broadcast being received at that moment is displayed. The name of the broadcast station may be displayed instead of the receiving frequency. The other divided region D12 at the moment is in the non-displayed state.

The auxiliary screen D2 of the display 34 displays the contents of the AM radio broadcast only on one of the divided regions which is also divided into two same as the main screen D1 is, while the other divided region enters in the non-displayed state. As the main screen D1, which has a bigger area, may mainly cause a noise source, only the main screen D1 is subject to the display control as shown in the case 1, and the display state using the entire screen may be kept for the auxiliary screen D2. Alternatively, the entire auxiliary screen D2 may be controlled into the non-display state by making only the main screen D1 to be used to perform various operations when the AM radio is used.

(Case 2) This is a case for stopping displaying of the main screen D1 and for displaying the contents of the AM radio broadcast only on the auxiliary screen D2. In such a case, as the main screen D1, being a big noise source, is in the non-active state, the noises can be substantially reduced. In this case, it is required that selection of receiving frequency or the like should be done by viewing only the auxiliary screen D2. Therefore, as shown in FIG. 3, some operation keys 301, 302, 303 and 304 of the operating section 30 are arranged on the same surface on which the auxiliary screen D2 is provided. For example, the operation keys 301 and 302 are used to shift up and down the receiving frequency, while the operation keys 303 and 304 are used to turn up and down the volume of the AM radio broadcast.

Hereinafter, relationship between the displays 32, 34 and the bar antenna 22 will be described. The bar antenna 22 is desirably placed apart from the displays 32, 34, which are noise sources. FIGS. 7 and 8 are diagrams showing preferable arrangement of the bar antenna 22 corresponding to the case 1 and relationship between the bar antenna 22 and the main screen. The surface of the package 52 is divided by center line C which is connecting each middle point of the long sides thereof into two spaces S11 and S12. As shown in FIG. 7, if the divided region D11, which is in a displaying state, is included in the space S12, the bar antenna 22 is arranged in the other space S11. Specifically, the bar antenna 22 is arranged at the end of the package 52 that is most apart from the divided region D11, which is in a displaying state. Alternatively, as shown in FIG. 8, if the divided region D12, which is in a displaying state, is placed across the center line C and more than half of the divided region D12 is placed in the space S11, the bar antenna 22 is arranged in the other space S12. In such a case, the bar antenna 22 is arranged at the end of the package 52 that is most apart from the divided region D12, which is in a displaying state.

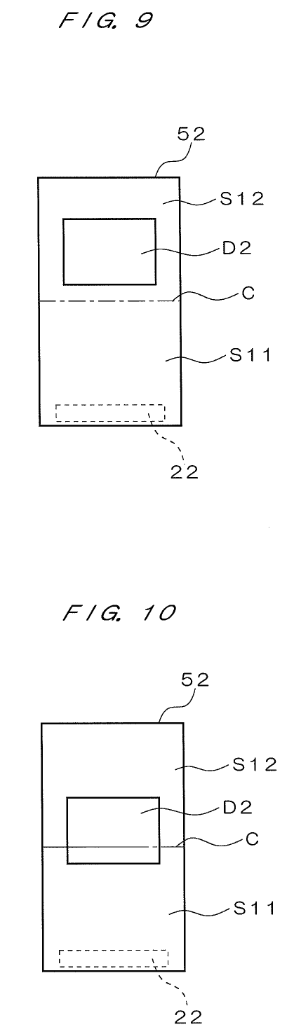

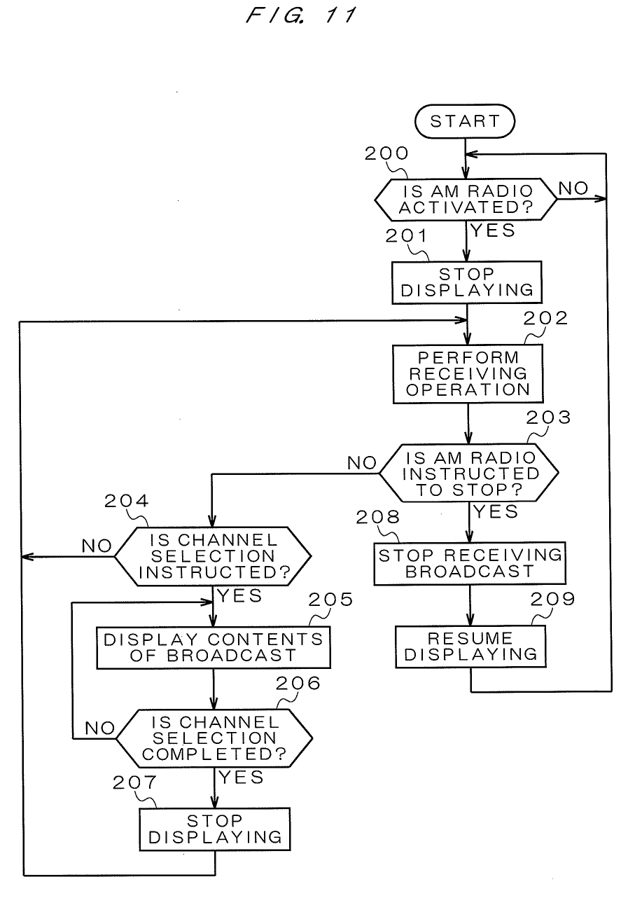

FIGS. 9 and 10 are diagrams showing preferable arrangement of the bar antenna 22 corresponding to the case 2 and relationship between the bar antenna 22 and the auxiliary screen. The surface of the package 52, which is including the auxiliary screen D2, is divided into two spaces S11 and S12 by center line C of the long sides of the package 52. As shown in FIG. 9, if the auxiliary screen D2 is included in the space S12, the bar antenna 22 is arranged in the other space S11. Specifically, the bar antenna 22 is arranged at the end of the package 52 that is most apart from the auxiliary screen D2. Alternatively, as shown in FIG. 10, if the auxiliary screen D2 is placed across the center line C and more than half of the auxiliary screen D2 is placed in the space S12, the bar antenna 22 is arranged in the other space S11.

As such, as the displayed state of the displays 32, 34 is changed when the AM radio broadcast is received by using the AM radio tuner section 20 provided for the cellular phone 100 of the embodiment, the noise to be mixed with the output audio of the AM radio caused by the displays 32, 34 as noise sources can be reduced. Particularly, a color liquid crystal display device driven by an active matrix of the TFT type is often used in the cellular phone 100 of these days in consideration of improvement of the vividness of the display and the fast response. But there is a well known problem that the color liquid crystal display device becomes a noise source for the AM radio tuner section 20 bigger than the liquid crystal display device driven by a segment electrode that performs monotone display. However, in case where the color liquid crystal display device are used for the displays 32, 34, in the invention, the noise included in the output audio of the AM radio can be reduced by means of changing the display state. Furthermore, size of the display is getting bigger and bigger these days, it is inevitable to have a noise caused by operations of the displays 32, 34 occurred, however, the noise can be reduced by changing the display state of the displays 32, 34 when the AM radio is used.

In a specific example, the display 32 (or the display 34) has a plurality of divided regions D11, D12 that can selectively stop display operations; and the control section 40 stops display operation of one of the divided regions when an instruction to commence the reception of the AM radio broadcast is provided (when the AM radio is activated). Thus, the area of the display as a noise source can be reduced, thereby it is possible to reduce the amount of noise included in the AM radio output audio. In this example, information on the broadcast contents is displayed on the other divided region on which display operation dose not stop. Therefore both noise reduction and improvement of operability when the AM radio is used can be achieved. Further, since the bar antenna 22 for the AM radio is placed apart from a divided region in which display operation is performed, it can reduce the noise that enters via the bar antenna 22 when the AM radio broadcast is received.

Alternatively, in another specific example, the display 32 with a main screen and the display 34 with an auxiliary screen are arranged apart from each other, and the control section 40 stops the display operation of the display 32 when the AM radio is activated. It makes possible to reduce the entire display area of the displays 32, 34 as the noise source, thereby it is possible to reduce the amount of noise included in the AM radio output audio. Specifically, it can eliminate the biggest noise source by stopping display operation of the display 32, which has the biggest display area, thus, it can efficiently reduce the noise.

Although the display state of the displays 32, 34 is controlled to have a small display area when the AM radio is used in the abovementioned embodiments, both of the displays 32, 34 may be controlled to be in the non-display state when the AM radio is used.

FIG. 11 is a flow chart showing an operational procedure of an exemplary modification of the cellular phone 100 when the AM radio broadcast is received, showing a controlling procedure relating to receiving of the AM radio broadcast and the display state control of the display 32 or the like. When the cellular phone 100 is turned on and operating, the control section 40 determines whether the AM radio is activated or not (step 200). If the user does not provide an instruction to activate, a negative determination is made and the judgment is repeated. When an instruction to activate the AM radio is provided, an affirmative determination is made in the step 200. Then, the control section 40 stops displaying of the displays 32, 34 (non-display state) (step 201), and performs the receiving operation of the AM radio broadcast by sending the instruction for the AM radio tuner section 20 (step 202).

In parallel to the operation of receiving the AM radio broadcast, the control section 40 determines whether it is instructed to stop the AM radio or not (step 203). If the user does not provide an instruction to stop, a negative determination is made. Next, the control section 40 determines whether the channel selection instruction is done or not (step 204). For example, the user can perform the channel selection instruction by shifting up or down the receiving frequency arbitrarily with the operating section 30, or directly designating the receiving frequency with the numeral keys provided for the operating section 30. If the channel selection instruction is not provided, a negative determination is made in the step 204, and the operation returns to the step 202 and the operation of receiving the AM radio broadcast is repeated.

If the channel selection is instructed, an affirmative determination is made in the step 204. Then, the control section 40 temporally resumes displaying of the displays 32 and 34 that have stopped displaying, and displays the contents of the AM radio broadcast to be received (step 205). Although the operation of displaying the contents may be performed by using the entire displays 32, 34 (both of the main screen and the auxiliary screen), it is desirable to reduce a noise by using the display control of the abovementioned case 1 or case 2.

Then, the control section 40 determines whether the channel selection operation has been completed or not (step 206). For example, it is considered that the channel selection operation has been completed if the operating section 30 has not been operated for a predetermined time (for example, for a second) after it was operated to select a channel. If the channel selection operation has not been completed, a negative determination is made in the step 206, and the operation returns to the step 205 and the contents of the AM radio broadcast is kept displayed. When the channel selection operation is completed, the control section 40 stops displaying on the displays 32, 34 again (step 207), and then the operation returns to the step 202 and the operation of receiving the AM radio broadcast is repeated.

When a user provides an instruction to stop the AM radio, an affirmative determination is made in the determination at the step 203, and then the control section 40 sends the instruction to the AM radio tuner section 20 and ends the operation of receiving the AM radio broadcast (step 208), while resuming the displaying operation by the displays 32, 34 (step 209), and returns to the step 200 and repeats determination on the AM radio activation.

As described above, when the AM radio is activated, the control section 40 stops the displaying operation of the displays 32, 34. Accordingly, an influence of the displays 32, 34 as noise sources is avoided, thus, any occurrence of noise caused by the displays 32, 34 can be eliminated. As a stopped state of the displaying operation of the displays 32, 34 are temporally released when the channel selection instruction is provided, both effects of improvement of operability and noise reduction can be achieved only by performing the requisite minimum display when the channel selection is done. Particularly, the noise temporally included in the output audio at the time of channel selection can be reduced by releasing the stopped state of the displaying operation for a part of the displayed region of the entire displays 32, 34 (when display control of cases 1, 2 is used in parallel).

The present invention is not limited to the abovementioned embodiments and various modifications are possible within a scope of the spirit of the present invention. For example, although the cellular phone 100 having two displays 32, 34 are described in the abovementioned embodiments, three or more displays may be provided. The control of the display state corresponding to the case 2 in this example, for an instance, it is desirable to keep displaying only with the smallest display area and stops display operation of the other displays. That can minimize the noise even if many displays are provided.

In the operation procedure described with reference to FIG. 11, a mute signal may be input from the control section 40 into the audio output section 24 to make a mute processing for output audio of the AM radio, when displaying is temporally resumed at the time of the channel selection. Since the output audio is muted by the mute processing, it can be prevented from outputting the rough sound includes noise caused by displaying temporally resumed. Actually, the contents of the AM radio broadcast may often be output improperly at the time of the channel selection because of frequency sweeping. Therefore, it may not be serious problem even if the mute processing is performed at the time of the channel selection.

Although the cellular phone 100 is provided with the AM radio function in the abovementioned embodiments, the present invention can be applied to another mobile device with a display, which is a noise source. For example, the present invention can be applied to the case where the AM radio function is added to the PDA.

According to the present invention, the display state of the display unit is changed when the AM radio broadcast is received, thereby it is possible to reduce noise mixed into the output audio of the AM radio broadcast caused by the display unit.

1. A mobile device equipped with an AM radio comprising a processing unit integrated with an AM radio tuner unit, wherein the processing unit performs a predetermined process while displaying operational contents on a display unit and the AM radio tuner unit receives the AM radio broadcast and outputs a demodulated audio signal, comprising:
an operating unit for providing an instruction to commence the reception of the AM radio broadcast by said AM radio tuner unit; and
a display state controlling unit for changing the display state of said display unit when said instruction to commence the reception is provided by using said operating unit.

2. The mobile device equipped with an AM radio according to claim 1, wherein said display unit is a color liquid crystal display device.

3. The mobile device equipped with an AM radio according to claim 1, wherein the process performed by said processing unit is a speech processing as a portable telephone.

4. The mobile device equipped with an AM radio according to claim 1,
wherein said display unit in display operation is a noise source to said AM radio tuner unit, and
wherein said display state controlling unit changes the display state of said display unit so as to reduce the noise to be mixed with said AM radio tuner unit from said display unit.

5. The mobile device equipped with an AM radio according to claim 1,
wherein said display unit has a plurality of divided regions where display operation can be selectively stopped, and
wherein said display state controlling unit stops the display operation of a part of said plurality of divided region when said instruction to commence the reception is provided.

6. The mobile device equipped with an AM radio according to claim 5, comprising:
broadcast contents display controlling unit for displaying information on the broadcast contents being received by said AM radio tuner unit instead of the operational contents of said processing unit or together with the operational contents on said display unit;
wherein the information on said broadcast contents is displayed on the remaining of said divided region in which display operation is not stopped.

7. The mobile device equipped with an AM radio according to claim 5,
wherein said AM radio tuner unit has a bar antenna whose magnetic core is wound with a coil, and remaining of said divided regions in which display operation is not stopped are arranged in one of the spaces separated in the middle of longitudinal sides in a package having a solid shape oblong in one direction, and said bar antenna is arranged apart in other space.

8. The mobile device equipped with an AM radio according to claim 5,
wherein said AM radio tuner unit has a bar antenna whose magnetic core is wound with a coil, and more than half of said remaining divided regions in which display operation is not stopped are arranged in one of the spaces separated in the middle of longitudinal sides in a package having a solid shape oblong in one direction, and said bar antenna is arranged apart in other space.

9. The mobile device equipped with an AM radio according to claim 5,
wherein said AM radio tuner unit has a bar antenna whose magnetic core is wound with a coil, and said bar antenna is arranged along the edge of said package that is most apart from said remaining divided regions in which display operation is not stopped in a package having a solid shape oblong in one direction.

10. The mobile device equipped with an AM radio according to claim 1,
wherein said display unit has a plurality of display regions which are set in different spaces, and
wherein said display state controlling unit stops the display operation of a part of said plurality of display region when said instruction to commence the reception is provided.

11. The mobile device equipped with an AM radio according to claim 10,
wherein said display state control unit stops display operation of said display region with the biggest area.

12. The mobile device equipped with an AM radio according to claim 10,
wherein said display state control unit stops operation of said display regions except for said display region with the smallest area.

13. The mobile device equipped with an AM radio according to claim 10,
wherein said AM radio tuner unit has a bar antenna whose magnetic core is wound with a coil, and remaining of said display regions in which display operation is not stopped are arranged in one of the spaces separated in the middle of longitudinal sides in a package having a solid shape oblong in one direction, and said bar antenna is arranged apart in other space.

14. The mobile device equipped with an AM radio according to claim 10,
wherein said AM radio tuner unit has a bar antenna whose magnetic core is wound with a coil, and more than half of said remaining display regions in which display operation is not stopped are arranged in one of the spaces separated in the middle of longitudinal sides in a package having a solid shape oblong in one direction, and said bar antenna is arranged apart in other space.

15. The mobile device equipped with an AM radio according to claim 10,
wherein said AM radio tuner unit has a bar antenna whose magnetic core is wound with a coil, and said bar antenna is arranged along the edge of said package that is most apart from said remaining display regions in which display operation is not stopped in a package having a solid shape oblong in one direction.

16. The mobile device equipped with an AM radio according to claim 1,
wherein said display state controlling unit stops the display operation of display unit when said instruction to commence the reception is provided.

17. The mobile device equipped with an AM radio according to claim 16,
wherein a channel selection instruction for switching a receiving frequency of a broadcasting wave to be received by said AM radio tuner unit is performed by using said operating unit; and
said display state controlling unit temporally releases a stopped state of the display operation of said display unit when said channel selection instruction is provided.

18. The mobile device equipped with an AM radio according to claim 17,
wherein the stopped state of the display operation of said display unit is released for a part of the entire display regions of said display unit.

19. The mobile device equipped with an AM radio according to claim 17, further comprising:
an audio output unit for outputting an audio corresponding to an audio signal output from said AM radio tuner unit from a speaker or an earphone;
wherein said audio output unit performs a mute processing for breaking output of the audio when the stopped state of display operation of said display unit is released as said channel selection instruction is provided.
